(19) United States
(12) Patent Application Publication
(10) Pub. No.: US 2014/0318832 A1
(43) Pub. Date: Oct. 30, 2014

(54) FABRICATION METHOD OF A RIGID-FLEXIBLE CIRCUIT BOARD AND RIGID-FLEXIBLE PRINTED CIRCUIT BOARD

(71) Applicants: Zhuhai Founder Tech. Hi-Density Electronic Co., Ltd., Zhuhai City, Guangdong (CN); Peking University Founder Group Co., Ltd., Beijing (CN)

(72) Inventors: Yong Huang, Zhuhai City (CN); Zhengqing Chen, Zhuhai City (CN)

(21) Appl. No.: 14/129,011

(22) PCT Filed: Sep. 25, 2012
(86) PCT No.: PCT/CN2012/081935

§ 371 Date: Jul. 17, 2014

(30) Foreign Application Priority Data
Nov. 18, 2011 (CN) 201110369904.8

(51) Int. Cl. H05K 3/46; H05K 1/02

(52) U.S. Cl. CPC H05K 3/46; H05K 1/02; H05K 2203/061
USPC 174/254; 29/830

(57) ABSTRACT

A manufacturing method of an anode foil for an aluminum electrolytic capacitor is provided, which comprises a first step of forming a porous oxide film, i.e. subjecting an etched foil having etched holes thereon to an anodic oxidation process to form a porous oxide film on both the outer surface of the etched foil and the inner surface of etched holes, and a second step of forming a dense oxide film, i.e. converting the porous oxide film into the dense oxide film. The method can be used to manufacture an anode foil for various voltage ranges, e.g. an ultra-high voltage anode foil whose voltage is more than 800 vf, and the method can increase specific capacity, reduce power consumption, simplify the process, and increase production efficiency.

### CROSS-REFERENCE TO RELATED APPLICATIONS

The present application claims priority to International Application No. PCT/CN2012/081935 which was filed on Sep. 25, 2012 and claims priority to Chinese Patent Application No. 201110369904.8 filed Nov. 18, 2011.

### STATEMENT RE: FEDERALLY SPONSORED RESEARCH/DEVELOPMENT

Not Applicable

### FIELD OF THE INVENTION

The present invention relates to the field of printed circuit board (PCB) technology, and particularly, to a fabrication method of a rigid-flexible PCB and a rigid-flexible PCB fabricated by the fabrication method.

### BACKGROUND OF THE INVENTION

With continuous development of production technology, all electronic products tend to become light and small. Various mini-portable electronic products such as mobile phones, digital cameras and the like are results under development of High Density Interconnect (HDI) technology. HDI is a technique in which circuit board layers can be connected to each other through forming microchannels, and is the latest circuit board process technique at present. Such HDI process works in cooperation with a build up process to enable circuit boards to become thin and small. The build up process is based on a double-sided or four-sided circuit board, wherein circuit layers are sequentially built up outside the circuit board using a sequential lamination technique. Additionally, blind holes are used as interconnections between build-up layers, while blind holes and buried holes connecting between parts of the layers can save spaces on a board surface where were occupied by through holes, such that limited outer area can be used for wiring and soldering components as much as possible. A multilayer PCB with required number of layers can be thus obtained through repeating the build up process.

At present, PCBs may be divided into rigid PCBs, flexible PCBs (FPCs for short) and rigid-flexible PCBs according to different strengths of insulation materials used therein. A rigid-flexible PCB is a PCB including one or more rigid regions and one or more flexible regions. As a combination of rigid board and flexible board, it has advantages of both the rigid board and the flexible board. Based on the features of the FPC that it can be freely bent, wound and folded, products made of rigid-flexible PCBs are easy to be assembled. They can be folded to form well compact packages, omitting the connections and installations of wires and cables, reducing or omitting the soldering between connectors and terminals, reducing both space and weight, and reducing or avoiding electrical interference so as to improve electrical performance, and thus completely satisfying the needs of the electronic devices (or products) to develop towards lightweight and miniaturization as well as multifunction. Especially, products using both HDI techniques and rigid-flexible PCBs are widely used for being thin, light, flexible, easy to meet 3-dimensional assembly requirements. With buried holes and/or blind holes, fine conductor width and spacing, multilayer, and other characteristics, features of lightweight and smallness of circuit boards are particularly reflected.

At present, processing materials of rigid-flexible PCBs include rigid sheets and flexible sheets. During processing, a rigid sheet and a flexible sheet are generally processed separately, and then the two sheets are laminated together using a prepreg (prepreg sheet) after being stacked. The present inventors note that in this fabrication method, an entire layer of a rigid-flexible PCB in which a flexible region is located is made of a flexible sheet, which causes flexible sheets to be used in rigid regions, waste regions (cutting regions) and other regions of the PCBs where flexible sheets are not necessary to be used, thus utilization of a flexible sheet, especially a binder-free-type flexible copper clad laminate (FCCL, which is a processing material of flexible CPBs), is reduced, resulting in waste of flexible sheets. Meanwhile, fabrication costs of FCCLs are relatively high, which increases virtually fabrication costs of electronic devices (or products) using such PCBs. Additionally, in order to reduce flow of prepreg in regions (i.e., rigid-flexible regions) where rigid regions and flexible regions overlap each other, low flow prepregs are generally used in fabricating rigid-flexible PCBs; while low flow prepregs are more expensive than ordinary prepregs, which directly increases costs of electronic devices (or products). Estimation shows that fabrication cost of a rigid-flexible PCB is 5-7 times that of a standard FR-4 rigid board at present, high costs limit further applications and developments of rigid-flexible PCBs. In order to control costs of rigid-flexible PCBs, it is primary to lower costs of flexible sheets.

It can be seen that, in current fabrication methods of rigid-flexible PCBs, since both use of a mixture of various materials and processing of a multilayer board are involved, the fabrication cost is high and the fabrication is difficult, and generally, such method is only suitable for fabricating a rigid-flexible PCB with less than ten layers.

### SUMMARY OF THE INVENTION

In view of the disadvantages that fabrication costs of rigid-flexible PCBs are high and fabrications are difficult in the prior art, the technical problems to be solved by the present invention are to provide a fabrication method of a rigid-flexible PCB with low fabrication cost, and to provide a rigid-flexible PCB fabricated by the fabrication method.

A technical solution used to solve the technical problem of the present invention is a fabrication method of a rigid-flexible PCB, the fabrication method includes:

fabricating a rigid board including a flexible window region (or a plurality of flexible window regions);

embedding at least one flexible board unit into the flexible window region of the rigid board;

forming at least one build-up layer on one or both sides of the rigid board with the embedded flexible board unit; and

removing a portion covering a flexible region of the flexible board unit from the build-up layer, so as to form the rigid-flexible PCB.

Preferably, the rigid board comprises a forming region, and the forming region comprises a rigid region and the flexible window region; step of fabricating a rigid board including the flexible window region specifically includes:

performing pattern processing on the rigid region of the rigid board; and

performing window cutting on the rigid board, wherein a window position where the window cutting is performed forms the flexible window region of the rigid board.

Further preferably, when performing window cutting on the rigid board, the flexible window region has a same size as the flexible board unit which is embedded in a position corresponding to the flexible window region.

Preferably, the step of forming at least one build-up layer on one or both sides of the rigid board with the embedded flexible board unit specifically includes: laminating a prepreg and a copper foil on one or both sides of the rigid board with the embedded flexible board unit, then performing drilling, plating and pattern transfer on the rigid board, and thus forming a first build-up layer on the rigid board with the embedded flexible board unit; or continuously forming a second build-up layer according to the process sequence until multiple build-up layers are formed.

Preferably, the step of removing a portion covering a flexible region of the flexible board unit from the build-up layer specifically is: performing controlled-depth cutting on the build-up layer along a border of a region of the build-up layer corresponding to the flexible region of the flexible board unit, and then removing the portion corresponding to the flexible region from the build-up layer.

Further preferably, before laminating the prepreg, window cutting is performed on the prepreg, window region cut in the prepreg corresponds to the flexible region of the flexible board unit and a border of the window region of the prepreg corresponds to a common border of the flexible region and a rigid-flexible region of the flexible board unit;

The prepreg is a low flow prepreg or a no flow prepreg.

Preferably, the window region of the prepreg has a same length as the rigid-flexible region, and has a width of 0-500 μm.

Preferably, before the step of embedding the at least one flexible board unit into the flexible window region of the rigid board, the method further includes fabricating the at least one flexible board unit, and specifically includes:

step S21: performing pattern processing on a flexible sheet; and

step S23: bonding a peelable protection film onto the flexible sheet subjected to the pattern processing, bonded position of the peelable protection film corresponding to the flexible region of the flexible board unit.

Preferably, the step S23 further includes:

performing window cutting on the peelable protection film, wherein a window position where the window cutting is performed corresponds to the rigid-flexible region of the flexible board unit; and bonding the peelable protection film subjected to the window cutting onto the cover film, wherein a position where the peelable protection film is bonded onto the cover film corresponds to the flexible region of the flexible board unit.

Preferably, step S22 is further included between step S21 and step S23, and step S22 includes: covering the flexible sheet with a cover film; and in step S23, step of bonding the peelable protection film onto the flexible sheet subjected to the pattern processing specifically is bonding the peelable protection film onto the flexible sheet subjected to the pattern processing by attaching the peelable protection film onto the cover film.

Further preferably, in step S22, the cover film has a thickness ranging from 20 μm to 150 μm;

In step S23, the peelable protection film has a thickness ranging from 20 μm to 150 μm;

A method for performing window cutting on the peelable protection film is a laser cutting method or a die cutting method or a mechanical milling method.

The present invention also provides a rigid-flexible PCB, which is fabricated by the above fabrication method.

According to a fabrication method of the present invention, the flexible board unit is embedded in the rigid board, and a wiring pattern on the flexible board is connected with a wiring pattern on a layer in which the rigid board is located, such that when fabricating a rigid-flexible PCB, it is only necessary to provide the flexible window region in the rigid board and dispose the flexible board unit in the flexible window region accordingly, without using flexible sheet in an entirety layer in which the flexible region of the rigid-flexible PCB is located, thus significantly reducing waste of flexible sheets, and accordingly lowering fabrication cost of a rigid-flexible PCB; at the same time, in a rigid-flexible PCB fabricated by such fabrication method, as the flexible board and the rigid board have a relatively small overlapping area, expansion and contraction variations of the flexible sheet in the flexible board are substantially consistent with those of the rigid sheet in the rigid board, and when performing lamination, undesirable phenomena such as misalignment of patterns, dislocations and the like due to inconsistent expansion and contraction variations will not occur. When performing drilling, hole cleaning and hole metallization processes, as the rigid region is a completely rigid sheet, processing thereof can be performed in full accordance with machining process and machining parameters of a rigid board, thus testing and debugging are omitted; as to the flexible region, when fabricating a fine pattern, small size machining may be used because the flexible board unit has small expansion and contraction variations and is difficult to be damaged, and meanwhile, undesirable phenomena such as open circuit, short circuit and the like may be effectively prevented from occurring, degree of difficulty in fabricating a rigid-flexible PCB is thus lowered and quality of a rigid-flexible PCB is effectively improved.

In summary, the beneficial effects of the present inventions are: significantly lowering fabrication costs of rigid-flexible PCBs, improving production yield and reliability of PCBs, and particularly improving connection reliability of PCBs; lowering degree of difficulty in fabricating rigid-flexible PCBs, and being especially suitable for fabricating rigid-flexible PCBs with four or more than four layers.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a flow chart of a fabrication method of a rigid-flexible PCB of the present invention;

FIG. 2 is a diagram showing processing steps of fabricating a Plus one HDI rigid-flexible PCB in Embodiment 1 of the present invention (no window cutting is performed on prepreg);

FIG. 3 is a diagram showing processing steps of fabricating a Plus two HDI rigid-flexible PCB in Embodiment 1 of the present invention (no window cutting is performed on prepreg);

FIG. 4 is a diagram showing processing steps of fabricating a Plus one HDI rigid-flexible PCB in Embodiment 1 of the present invention (window cutting is performed on prepreg);

FIG. 5 is a diagram showing processing steps of fabricating a Plus two HDI rigid-flexible PCB in Embodiment 1 of the present invention (window cutting is performed on prepreg);

FIG. 6 is a schematic diagram illustrating window cutting of a rigid board in Embodiment 1 of the present invention;

FIG. 7 is a schematic diagram of processing a flexible board unit in Embodiment 1 of the present invention;

FIG. 8 is a processing schematic diagram of embedding a flexible board unit into a flexible window region of a rigid board of the present invention; and

FIG. 9 is a processing schematic diagram of performing window cutting and stacking on a prepreg in Embodiment 3 of the present invention.

In figures: 1—flexible board unit; 2—rigid sheet; 3—outline region; 4—forming region; 5—flexible window region; 6—prepreg; 7—copper foil; 8—controlled-depth cutting position; 9—build-up layer; 10—prepreg window region; 11—flexible sheet; 111—flexible sheet conductive layer ; 112—flexible sheet dielectric layer; 12—cover film; 13—peelable protection film; 21—rigid sheet conductive layer; 22—rigid sheet dielectric layer; 23—rigid-flexible region; 24—flexible region.

### DETAILED DESCRIPTION OF THE EMBODIMENTS

For enabling the person skilled in the art to better understand the technical solutions of the present invention, the present invention is further described below in details in conjunction with accompanying drawings and specific implementations.

The present invention provides implementations of a fabrication method of a rigid-flexible PCB, the fabrication method includes the following steps:

fabricating a rigid board including a flexible window region;

embedding at least one flexible board unit into the flexible window region of the rigid board;

forming at least one build-up layer on one or both sides of the rigid board with the embedded flexible board unit; and

removing a portion covering a flexible region of the flexible board unit from the build-up layer, so as to form the rigid-flexible PCB.

Wherein, the flexible region is a bendable soft board exposed on a surface of a rigid-flexible board; the rigid-flexible region is a portion of the soft board which is embedded in interior of the rigid-flexible board and laminated in the rigid board, i.e., a portion of the flexible board unit where the flexible board unit and the rigid board overlap after the flexible board unit is embedded into the rigid board. Below, the above implementations will be described by way of specific embodiments.

### Embodiment 1

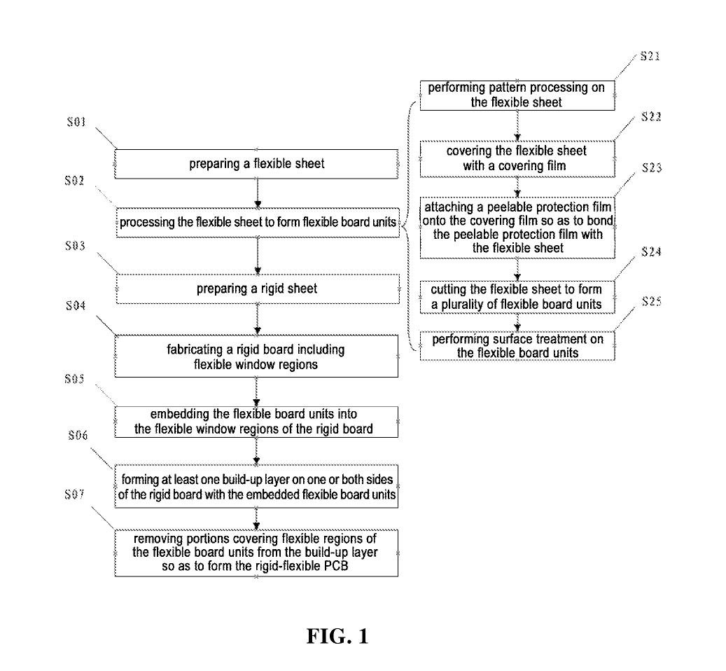

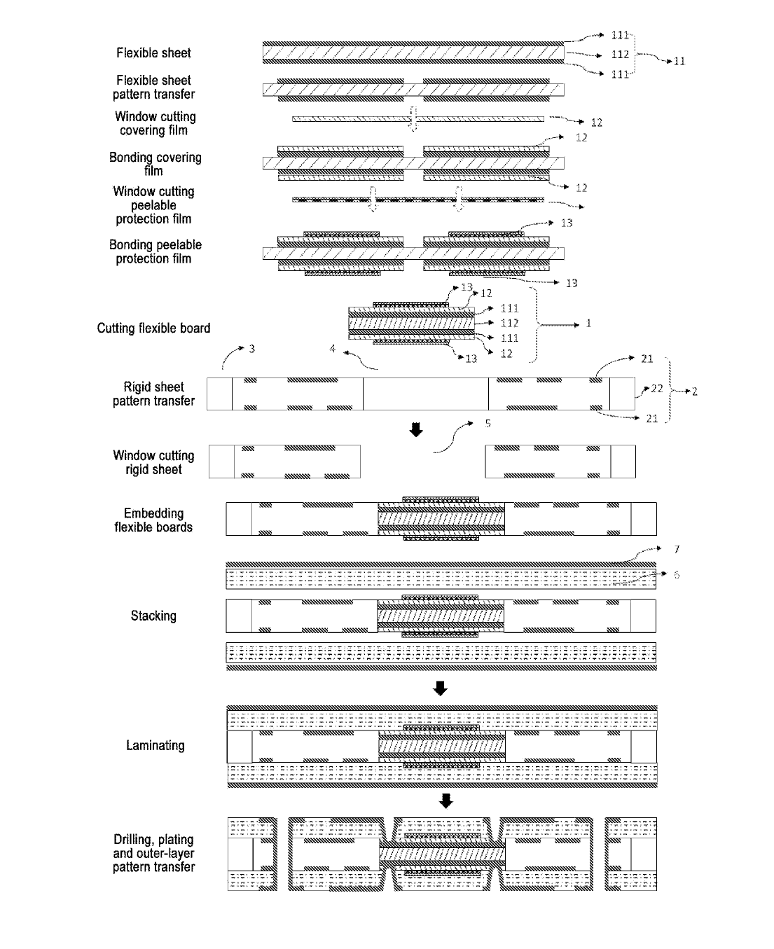

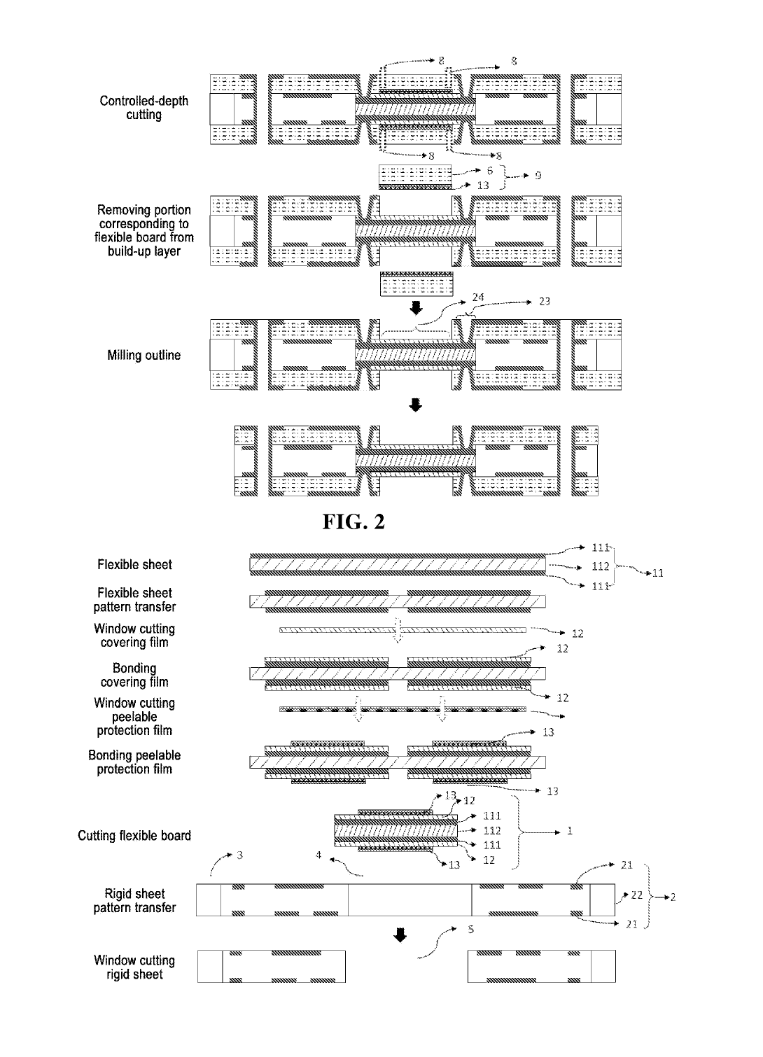

The circuit board fabricated in this embodiment is a Plus One HDI rigid-flexible PCB, and FIG. 2 is a diagram showing processing steps of fabricating the Plus one HDI rigid-flexible PCB. As illustrated in FIG. 1, the fabrication method specifically includes the following steps:

Step S01: preparing a flexible sheet. In this embodiment, the flexible sheet 11 includes a flexible sheet dielectric layer 112 and flexible sheet conductive layers 111 provided at both sides of the flexible sheet dielectric layer 112.

Step S02: processing the flexible sheet 11 to form small flexible board units. Each small flexible board unit is divided into a rigid-flexible region and a flexible region.

The step of processing the flexible sheet specifically includes:

Step S21: performing pattern processing on the flexible sheet. That is, transferring a wiring pattern that needs to be arranged in the flexible board onto the flexible sheet conductive layers 111 on both sides of the flexible sheet dielectric layer 112, respectively, through a patterning process. Alternatively, according to requirement of a customer, a flexible sheet dielectric layer 112 with a conductive layer on single side thereof can be selected, or the transfer of wiring pattern is only performed on the conductive layer on one side of the flexible sheet dielectric layer.

Step S22: preparing a cover film, covering the patterned flexible sheet with the cover film. Herein, window cutting may or may not be performed on the cover film 12 in advance according to practical processing requirements, and the cover film 12 is laminated onto the flexible sheet conductive layers 111. The cover film 12 has a thickness ranging from 20 μm to 150 μm. If window cutting need to be performed in advance, a method for window cutting may adopt laser cutting, die cutting or mechanical milling. The cover film is used to protect metallic wires formed on the flexible sheet, specifically, achieves effects of preventing the metallic wires from oxidation, outside wear, contamination, and the like, and at the same time increases working life and using safety of the rigid-flexible board. Therefore, this preferable step is usually added when processing flexible board units.

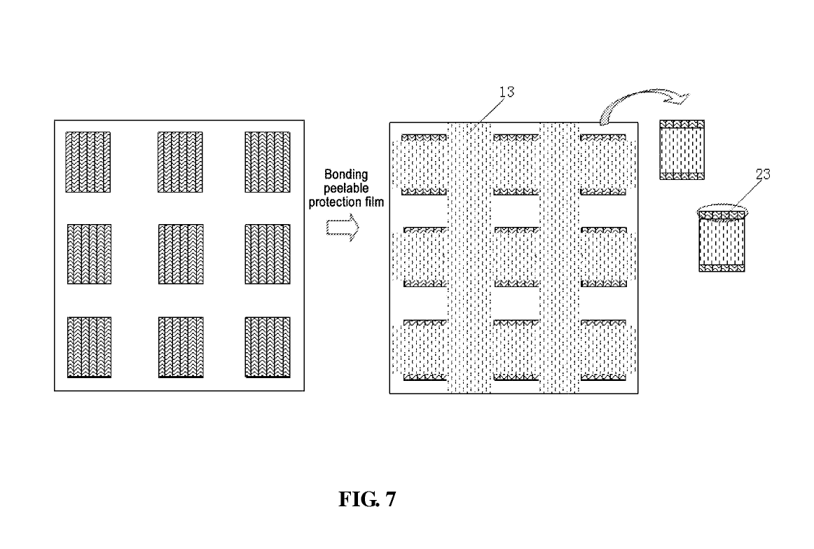

Step S23: bonding a peelable protection film onto the flexible sheet subjected to the pattern processing, such that the bonded position of the peelable protection film corresponds to the flexible regions of the flexible board units. Window cutting is performed on the peelable protection film. Positions where window cutting is performed (also referred to as window positions) correspond to rigid-flexible regions of the flexible board units. The peelable protection film subjected to the window cutting is bonded onto the cover film, and the peelable protection film is bonded to positions on the cover film corresponding to the flexible regions of the flexible board units. As illustrated in FIG. 7, through performing window cutting on the peelable protection film 13, when the peelable protection film 13 is attached to the cover film so as to be bonded onto the flexible sheet subjected to the pattern processing, the rigid-flexible region 23 covered by the cover film 12 is exposed, such that the peelable protection film 13 is only provided at the positions on the cover film corresponding to the flexible regions 24 of the flexible board units, thereby the peelable protection film 13, the cover film 12 and the flexible sheet are bonded together tightly.

At this point, the flexible sheet includes the flexible sheet dielectric layer 112, and the flexible sheet conductive layers 111, the cover films 12 and the peelable protection films 13 provided on both sides of the flexible sheet dielectric layer 112.

A method for performing window cutting on the peelable protection film may adopt laser cutting, die cutting or mechanical milling.

In this embodiment, the peelable protection film preferably has a thickness ranging from 20 μm to 150 μm and includes an upper layer and a lower layer. The upper layer is a polymer material and can be effectively bonded to a prepreg, a resin with copper foil in a resin layer, and the like. The lower layer is a peelable adhesive layer, which can be bonded to a cover film on a flexible sheet, a copper foil layer, a flexible sheet, and the like, and in step S23, the peelable adhesive layer of the peelable protection film 13 is bonded to the cover film 12.

Step S24: cutting the flexible sheet subjected to step S23 to form a plurality of flexible board units. After having been subjected to the above processings, the flexible sheet is cut to form a plurality of flexible board units 1. The formed flexible board units 1 have shapes and sizes matching those of the flexible window regions 5 in the rigid board. In practical fabrication process, this step is included in most cases. For purpose of efficient batch production, one flexible sheet may be cut into a plurality of flexible board units 1, size of each flexible board unit is such that the flexible board unit is embedded right in each of a plurality of flexible window regions 5 in one rigid board, or embedded in the same flexible window region 5 of a plurality of rigid boards. In summary, the cut plurality of flexible board units 1 have sizes matching those of the respective flexible window regions of the rigid board. A method for cutting the flexible sheet may adopt laser cutting, die cutting or mechanical milling.

Step S25: performing surface treatment on the flexible board units. Performing surface treatment on the flexible board units (mainly on the upper surface and lower surface thereof) is for the purpose of increasing surface roughness of the flexible board units, thus enhancing bonding force between the flexible board units and the prepreg. The treatment method includes brown oxide method and potassium permanganate corrosion method.

Step S03: preparing a rigid sheet. The rigid sheet comprises rigid sheet conductive layers 21 and a rigid sheet dielectric layer 22.

It should be noted that, there is no specific sequence order between steps S03, S04 and the above steps S01, S02. In some cases, manufacturers of rigid-flexible boards customize flexible board units subjected to step S02 with corresponding specifications from other manufactures instead of fabricating flexible board units themselves.

Step S04: fabricating a rigid board including flexible window regions. This step specifically includes:

Step S41: performing pattern processing on the rigid sheet 2 through a patterning process. In this embodiment, the rigid sheet 2 includes forming region 4 and outline region 3, the forming region of the rigid sheet is further divided into rigid regions and flexible window regions 5, and the pattern processing is performed on the rigid regions.

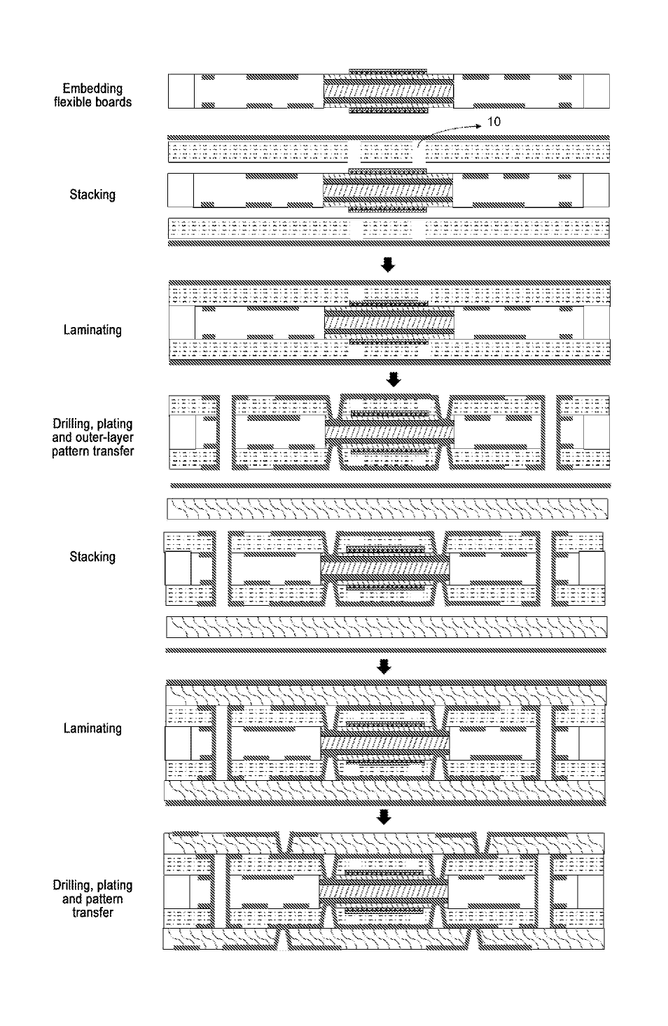

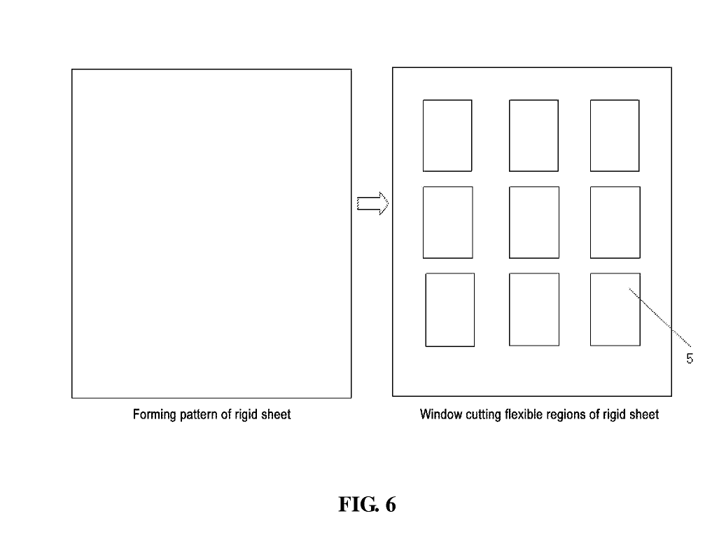

Step S42: performing window cutting on the rigid sheet, and window positions form the flexible window regions in the rigid sheet. When performing window cutting on the rigid sheet, the flexible window regions 5 have shapes and sizes in consistent with those of the flexible board units 1 embedded in the corresponding positions, such that the flexible board units may be right placed in the flexible window regions. As illustrated in FIG. 6, the method for performing window cutting on the rigid sheet may adopt laser cutting, die cutting or mechanical milling. The sequence order between step S41 and step S42 are interchangeable, that is, flexible window regions are first formed and pattern processing is then performed on the rigid regions.

Step S05: embedding the flexible board units into the flexible window regions of the rigid board. Wherein, the rigid board has a same thickness as the flexible board units, or has a thickness with a difference within 50 μm from the flexible board units.

Step S06: forming at least one build-up layer on one or both sides of the rigid board with the embedded flexible board units so as to obtain a rigid board including flexible boards. That is, laminating a prepreg and a copper foil on one or both sides of the rigid board with the embedded flexible board units, then performing drilling, plating and pattern transfer on the rigid board, thus forming a first build-up layer(s) on the rigid board with the embedded flexible board units; or continuously forming a second build-up layer according to the process sequence until multiple build-up layers are formed.

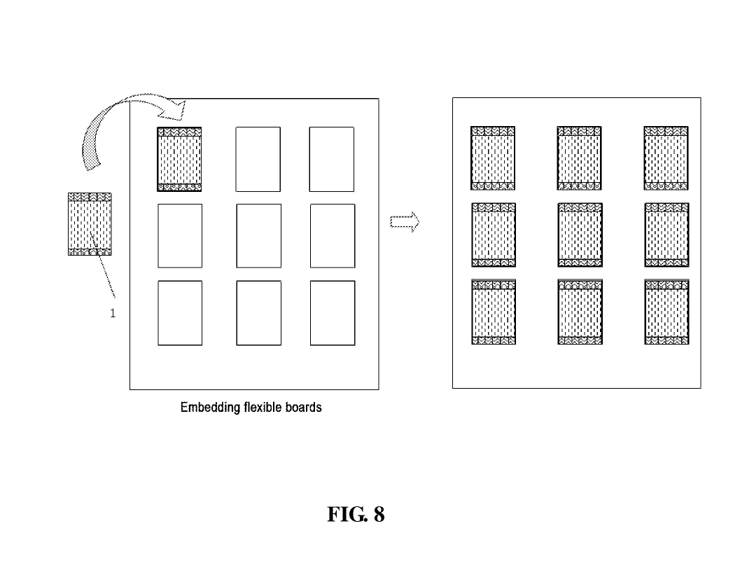

Step S61: stacking. Firstly, a copper foil 7 is placed, and a prepreg 6 is placed on the copper foil 7, the rigid sheet with the embedded flexible board units is then placed on the prepreg 6, and another prepreg 6 and another copper foil 7 are sequentially placed on the rigid sheet with the embedded flexible board units. Through the above stacking, a rigid board including flexible boards can be obtained. FIG. 8 illustrates a processing schematic diagram of embedding the flexible board units into the flexible window regions of the rigid sheet.

Step S62: form a build-up layer. A first lamination is performed on the rigid board subjected to Step S61, so as to make each layer of the rigid board, the flexible boards, the prepregs 6 and the copper foils 7 in the rigid board with the embedded flexible boards be bonded together tightly, and to enhance mechanical strength thereof. Then, processes of drilling, plating (hole metallization), outer-layer pattern transfer and the like are performed to form a build-up layer of the first lamination. Herein, electric connection between the rigid board and the flexible board units may be achieved through drilling and plating.

Step S07: removing portions covering the flexible regions of the flexible board units from the build-up layer so as to form a rigid-flexible PCB. In a Plus one HDI rigid-flexible PCB, the build-up layer 9 only includes one layer of rigid sheet closely attached onto the flexible boards, the prepreg and the copper foil.

Controlled-depth cutting is performed on the build-up layer along borders of regions corresponding to the flexible regions of the flexible board units, that is, along controlled-depth cutting positions 8 in FIG. 2. Herein, cutting depth is set to be such that the peelable protection film on the flexible board units can right be exposed or a distance from the cutting bottom to the peelable protection film is short, which causes portions of the build-up layer corresponding to the flexible regions of the flexible board units to be easily peeled off. In practical operation, preferably, the cutting depth is controlled to be such that a distance between the cutting bottom and the peelable protection film is 30-100 μm. In other words, the cutting depth should ensure that the peelable protection film, especially the flexible sheets under the peelable protection layer, is avoided from being cut. Moreover, the cover film can also protect the flexible sheets from being directly cut possibly due to inappropriate cut of the peelable protection layer, thus avoiding the production of waste. The controlled-depth cutting method may adopt mechanical controlled-depth milling, laser controlled-depth cutting or V-cutting.

After the controlled-depth cutting is completed, portions of the build-up layer above the flexible regions are removed. In this step, the portions of the build-up layer above the flexible regions may be removed together with the peelable protection film through peeling the peelable protection film 13 from the flexible board units, that is, the portions corresponding to the flexible regions are removed from the build-up layer.

S08: removing the outline region from the rigid board. It is common to use a milling process to remove the outline region, and thus the rigid-flexible PCB is fabricated.

The fabrication method in this embodiment is suitable for fabricating a Plus one HDI rigid-flexible PCB. In the rigid-flexible PCB fabricated by this method, the rigid regions and rigid-flexible regions thereof are used to mount electronic elements thereon, the flexible regions are mainly used to be bent so as to be connected with a circuit, and the flexible regions may or may not have electronic elements mounted thereon as required.

### Embodiment 2

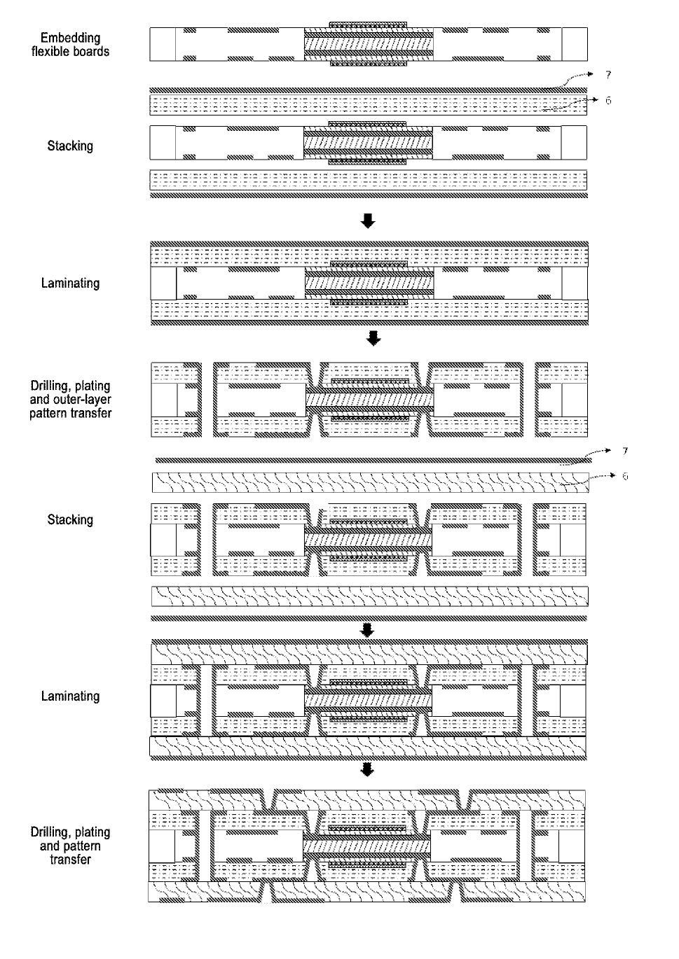

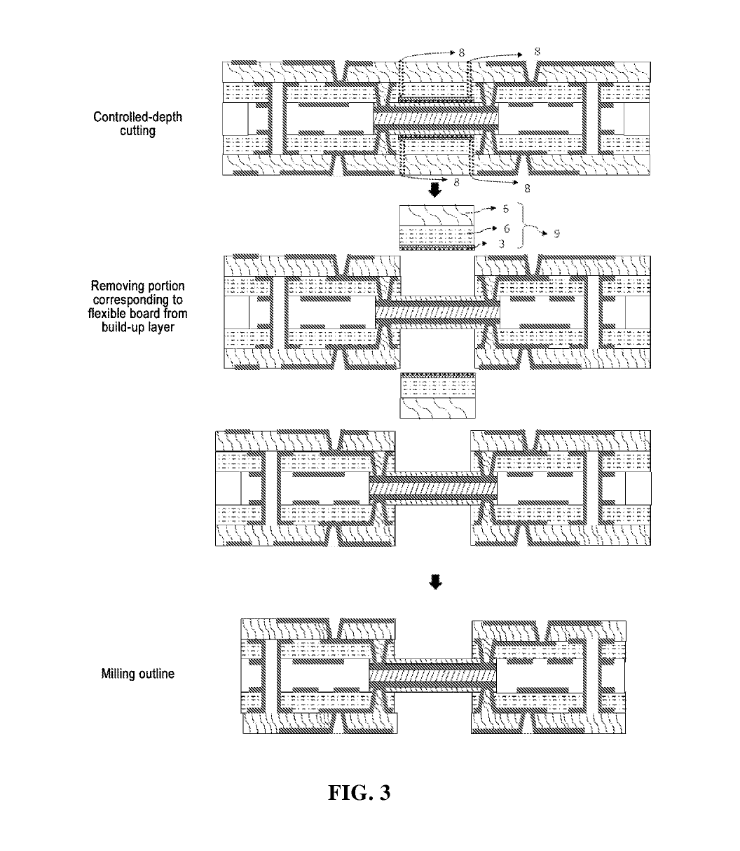

A circuit board fabricated in this embodiment is a high plus (Plus two or higher) HDI rigid-flexible PCB. FIG. 3 is a diagram showing processing steps of fabricating the HDI rigid-flexible PCB. In this embodiment, the high plus HDI rigid-flexible PCB is a Plus N (N≧2) HDI rigid-flexible PCB. As illustrated in FIG. 3, the method specifically includes the following steps:

fabricating an inner-layer board. This step includes the same steps as steps S01-S06 in Embodiment 1, the obtained rigid board with embedded flexible board units is the inner-layer board of this embodiment.

Adding a required number of layers of rigid sheets after the above step S62, and this step specifically includes:

Step S63: stacking. A copper foil 7 is first placed, a prepreg 6 is placed on the copper foil 7, the obtained inner-layer board is then placed on the prepreg 6, and a prepreg 6 and a copper foil 7 are sequentially placed on the inner-layer board. Through the above stacking, the number of layers of the inner-layer board is increased by one.

Step S64: laminating, drilling, plating and outer-layer pattern transfer. Another lamination is performed on the inner-layer board, such that each layer of the inner-layer board, the prepregs 6 and the copper foils 7 are bonded together tightly, and mechanical strength thereof are enhanced; and then processes of drilling, plating (hole metallization) and outer-layer pattern transfer are performed. Through drilling and plating, electric connection between this layer and the inner-layer board thereof (including the inner-layer board in the layer where the flexible boards are located, and the first build-up layer) is achieved.

For a Plus N HDI rigid-flexible PCB, steps S63 and S64 (stacking, laminating, drilling, plating and outer-layer pattern transfer) need to be repeated N−1 times until a Plus N rigid sheet with the embedded flexible board units and with desirable number of layers is obtained, and the value of N is determined by the number of layers required by the rigid board.

Wherein, an outer-layer pattern fabricated in a previous process serves as an inner-layer board of the PCB in a subsequent process, that is, a Plus N HDI rigid-flexible PCB may be subjected to processes including laminating, drilling, plating and pattern transfer N times to form outer-layer patterns, respectively, until the outermost-layer pattern is processed. In a high plus HDI rigid-flexible PCB, the build-up layer 9 comprises multiple layers of rigid sheets closely attached onto the flexible boards, the prepregs and the copper foils.

Step S07: removing portions covering the flexible regions of the flexible board units from the build-up layer so as to form the rigid-flexible PCB. That is, performing controlled-depth cutting on the above Nth build-up layer along borders of regions corresponding to the flexible regions of the flexible board units. Herein, cutting depth is set to be such that the peelable protection film on the flexible board units can right be exposed or a distance from the cutting bottom to the peelable protection film is short. In practical operation, preferably, the cutting depth is controlled to be such that a distance between the cutting bottom and the peelable protection film is 30-100 μm, that is, it should be ensured that the peelable protection film, especially the flexible sheets under the peelable protection layer, is avoided from being cut. The controlled-depth cutting may adopt mechanical controlled-depth milling, laser controlled-depth cutting or V-cutting.

After the controlled-depth cutting is completed, portions of the build-up layers above the flexible regions are removed. In this step, the portions of the build-up layers above the flexible regions may be removed together with the peelable protection film.

Step S08: removing the outline regions from the rigid board. milling process is usually used to remove the outline regions, and thus the rigid-flexible PCB is fabricated.

When a fabrication method of a rigid-flexible PCB described in this embodiment is used to fabricate a Plus two or higher HDI rigid-flexible PCB, based on a rigid board with embedded small flexible board units with build-up layer(s) thereon fabricated in Embodiment 1, respective build-up layers are successively added outside, and electric connections among respective layer are achieved by lamination, drilling and hole metallization, and cutting is finally performed to remove the outline regions of the rigid board. In a fabricated rigid-flexible PCB fabricated, the rigid regions and rigid-flexible regions thereof are used to mount electronic elements thereon, and the flexible regions are mainly used to be bent so as to be connected with a circuit.

### Embodiment 3

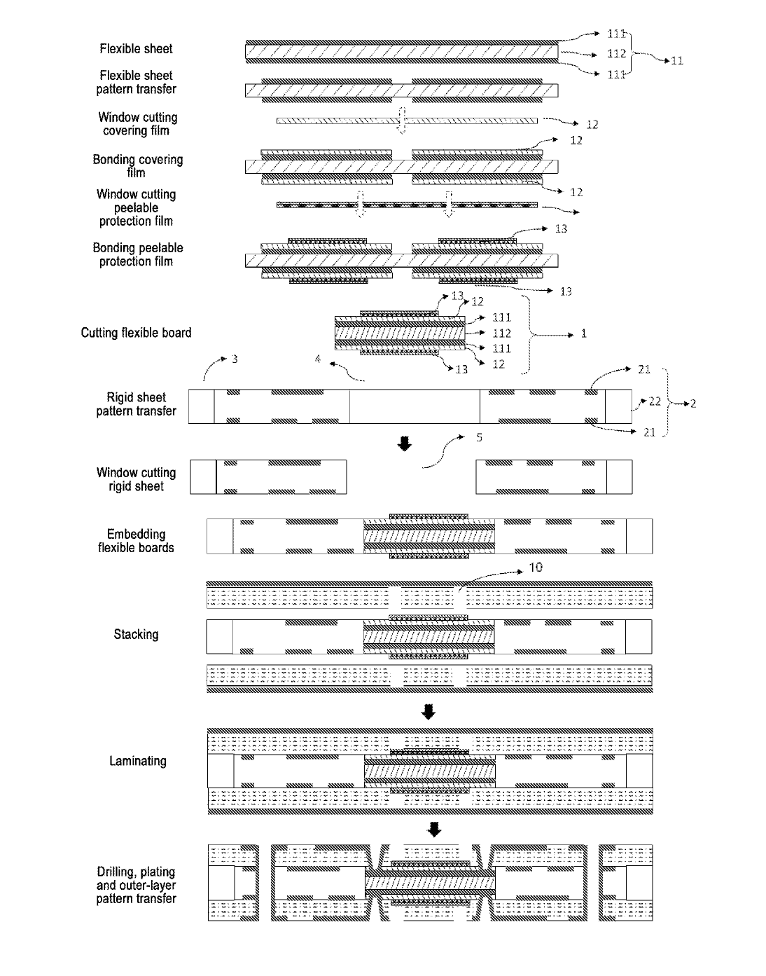

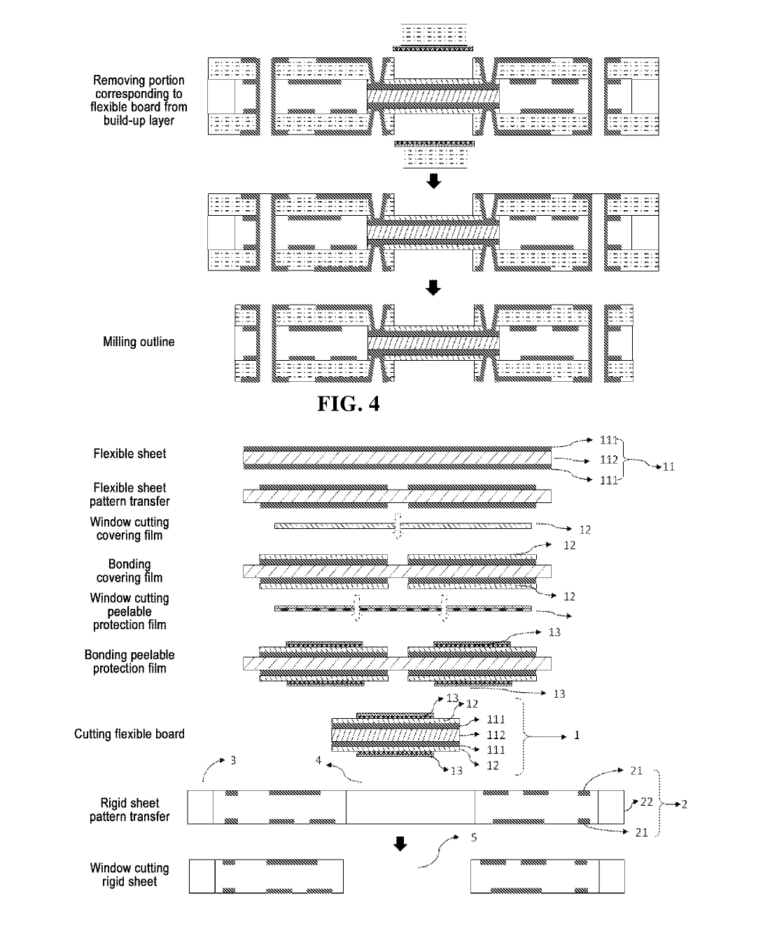

A circuit board fabricated in this embodiment is a Plus one HDI rigid-flexible PCB. As illustrated in FIG. 4, this embodiment differs from Embodiment 1 in that:

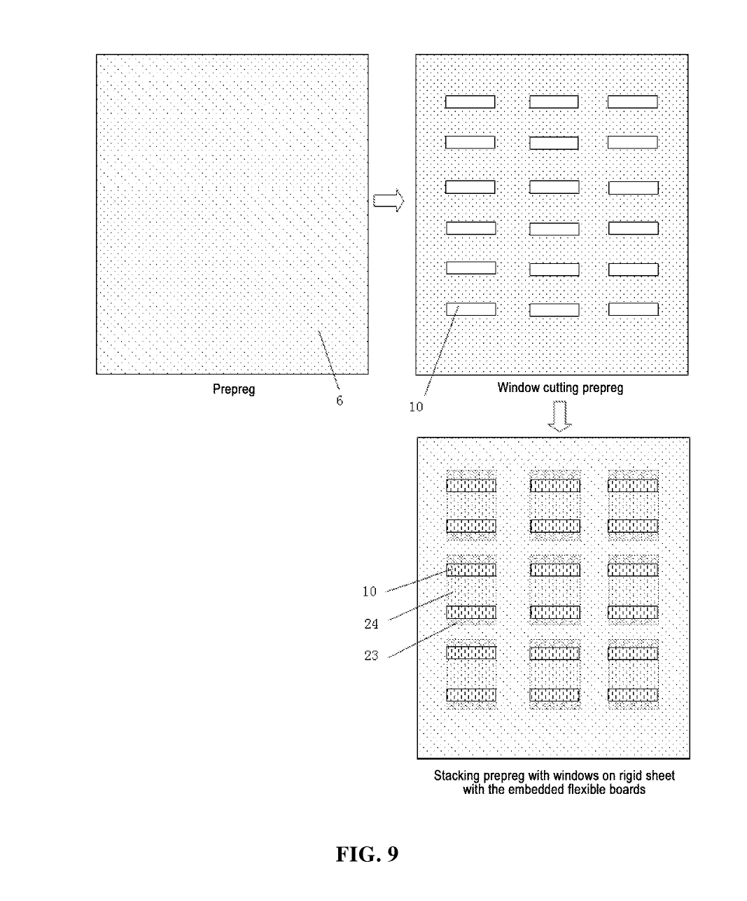

1) Corresponding to step S06 in Embodiment 1, in this embodiment, before stacking (S61), window cutting is first performed on the prepreg 6. Herein, the window regions cut in the prepreg correspond to the flexible regions of the flexible board units, and the borders of the window regions correspond to the common borders of the flexible regions and the rigid-flexible regions of the flexible board units. Size of the windows cut in the prepreg has the same length as that of the rigid-flexible regions, specifically, the length ranges from 0.5 mm to 3 mm, while the width of the window regions ranges from 0-500 μm, and the windows can be formed by mechanical milling or laser cutting or die cutting. FIG. 9 is a processing schematic diagram of performing window cutting and stacking on the prepreg in Embodiment 3 of the present invention. After window cutting on the prepreg is completed, other processes in step S06 in this embodiment are the same as those in step S06 in Embodiment 1.

2) Corresponding to step S07 in Embodiment 1, controlled-depth cutting is not necessary in this embodiment, and as window cutting has been performed on the prepreg 6 above the flexible regions in advance, it is only required to peel the peelable protection film and the build-up layer off the flexible board units directly.

Other steps in this embodiment are the same as those in Embodiment 1, and redundant description thereof is thus omitted.

In this embodiment, as window cutting is performed on the prepreg before stacking, a controlled-depth cutting process can be omitted, and processing costs are lowered to certain extent, However, as window cutting is performed, the resin ingredient in the prepreg may easily flow into the flexible regions when being heated, which leads to too much resin flow on surfaces of the flexible boards, such that serious residue phenomenon occurs in the rigid-flexible PCB fabricated by such method. Therefore, in order to avoid too much resin flow, the prepreg in this embodiment generally adopts low flow prepreg or no flow prepreg both with relatively higher costs. As window cutting is only performed on common borders of the flexible regions and the rigid-flexible regions with a cutting width of 0-500 μm, multilayer boards bear relatively uniform force at respective points during lamination, and compared to a case in which window cutting and removing is performed on portions of the prepreg corresponding to all flexible regions to prevent flow, this embodiment obtains better lamination effect and will not cause warping, wrinkles, or other problem.

### Embodiment 4

A circuit board fabricated in this embodiment is a high plus (Plus two or higher) HDI rigid-flexible PCB.

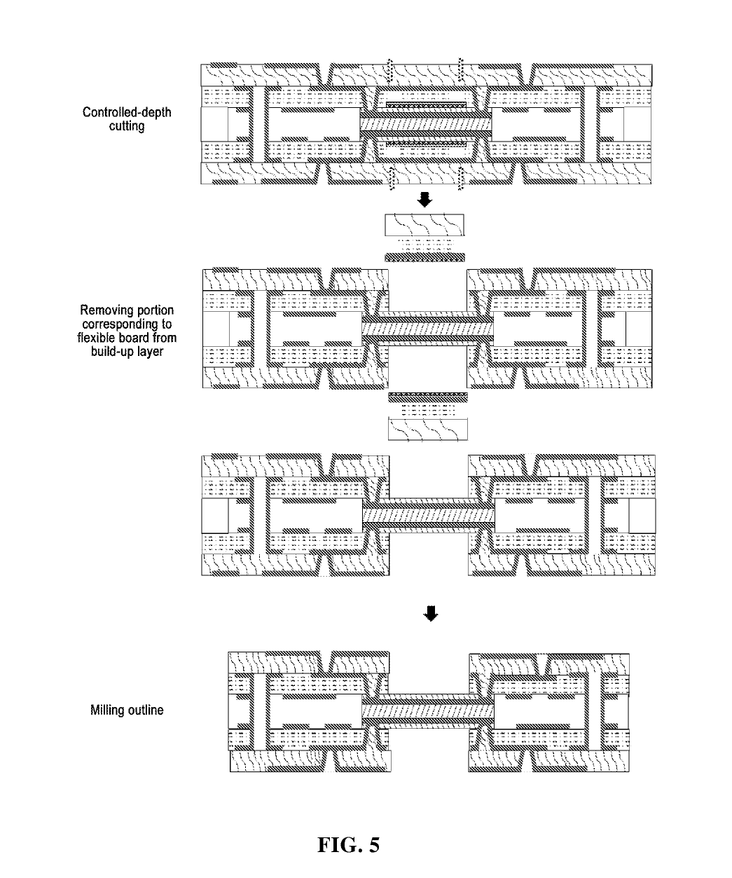

As illustrated in FIG. 5, this embodiment differs from Embodiment 2 in that:

1) Corresponding to step S06 in Embodiment 2, in this embodiment, window cutting is first performed on the prepreg 6 before stacking. During window cutting, window regions cut in the prepreg 6 correspond to the flexible regions of the flexible board units, borders of the window regions correspond to the common borders of the flexible regions and the rigid-flexible regions of the flexible board units, size of the windows cut in the prepreg has the same length as the rigid-flexible regions, specifically, the length ranges from 0.5 mm to 3 mm, width of the window regions ranges from 0 to 500 μm, and a method for window cutting may adopt mechanical milling, laser cutting or die cutting. FIG. 9 is a processing schematic diagram of performing window cutting and stacking on the prepreg in Embodiment 3 of the present invention. After window cutting on the prepreg is completed, other processes in step S06 in this embodiment are the same as those in step S06 in Embodiment 2.

2) Corresponding to step S07 in Embodiment 2, controlled-depth cutting is performed on the build-up layers along borders of the regions corresponding to the flexible regions of the flexible board units. Depth of the controlled-depth cutting arrives at the position of the windows regions of the prepregs.

Other steps in this embodiment are the same as those in Embodiment 2, and redundant description thereof is thus omitted.

In a rigid-flexible PCB fabricated through the present invention, the rigid regions and rigid-flexible regions thereof are used to mount electronic elements thereon, and the flexible regions are mainly used to be bent so as to be connected with a circuit.

When the fabrication method of a rigid-flexible PCB described in this embodiment is used to fabricate a high plus HDI rigid-flexible PCB, it is such that based on a fabricated Plus one HDI rigid-flexible PCB, respective rigid sheets are successively added to the outside of the fabricated HDI rigid-flexible PCB, and electric connections among respective rigid sheets are achieved through laminating, drilling and hole metallization, and cutting is finally performed to remove the outline regions.

In this embodiment, as window cutting is performed on the prepreg before stacking, the resin ingredient in the prepreg may easily flow into the flexible regions when being heated, which leads to too much resin flow on surfaces of the flexible boards, such that serious residue phenomenon occurs in the rigid-flexible PCB fabricated by such method. Therefore, in order to avoid too much resin flow, it is recommended to use a low flow prepreg or a no flow prepreg in this embodiment.

As in a rigid-flexible PCB, the expansion and contraction characteristics of the rigid sheet and those of the flexible sheet do not coincide with each other (generally, a flexible sheet has bigger expansion and contraction variations than a rigid sheet, and with the increase in size of a circuit board, a flexible sheet will have even bigger expansion and contraction variations), therefore, if stacking and laminating a rigid PCB and a flexible PCB having the same area, because of the inconsistent expansion and contraction variations between the two materials, during fabrication, even some minor differences may lead to misalignment of circuit patterns, dislocations and other undesirable phenomena, and eventually affect quality of the circuit board. However, by using the above method, pattern dislocations due to inconsistent expansion and contraction characteristics of materials can be avoided.

In addition, as a rigid sheet and a flexible sheet themselves have different characteristics, if a rigid-flexible board is fabricated by stacking and laminating a rigid PCB and a flexible PCB having the same area, it is required to employ special processes to perform special controls during processes of drilling, hole cleaning, and hole metallization, for example, suitable pulse width and pulse frequency are used during drilling, especially during laser drilling. During hole cleaning, as there are both a rigid sheet and a flexible board in a single hole, that is, a hole wall includes three materials: FR-4 (epoxy glass fiber board), PI (polyimide) and an adhesive layer, while PI is not resistant to strong alkali, the adhesive layer is not resistant to strong acid or strong alkali, therefore, a alkaline permanganate cleaning solution used in the current hole cleaning process is likely to cause over etching and form recessions in the hole wall, such that in the subsequent etching or plating process, liquor is reserved and copper cannot be plated; at present, plasma desmear is also used, however, as a plasma cleaning device is expensive and has limited working ability, it is not widely used; also, ultrasonic cleaning method is used within a alkaline permanganate desmear solution, thus an effect of hole cleaning is achieved through the combination of physical action and chemical action, however, such cleaning method still cannot avoid over etching on the hole wall. During hole metallization, depending on different liquors and process parameters, to obtain a preferable implementation so as to enable the respective process conditions to interact with each other, orthogonal experiment should be performed to determine the best parameter and process. The above special processes undoubtedly increase degree of difficulty of fabricating a rigid-flexible PCB, while these problems can be prevented from occurring by using the embodiments provided by the present invention. In addition, when fabricating a fine pattern on a flexible board, especially on a flexible board with large area, as the flexible is easily deformed and damaged, undesirable problems such as open circuit, short circuit and the like are likely to occur, whereas the flexible board units provided by the present invention can avoid these problems.

Embodiments of the present invention also provide a rigid-flexible PCB fabricated by any fabrication method of Embodiments 1-4. Wherein, Plus one HDI rigid-flexible PCBs can be fabricated through the fabrication methods of a rigid-flexible PCB described in Embodiment 1 or 3; high plus HDI rigid-flexible PCBs can be fabricated through the fabrication methods of a rigid-flexible PCB described in Embodiment 2 or 4. In the rigid-flexible boards fabricated by the above methods, there is no residual copper exists in a combined region of a flexible board and a rigid board, and accordingly there is no need to remove the residual copper (which is difficult to be removed) by etching; therefore, there is no immersion gold present in the combined regions when performing gold immersion, which are more consistent with the cleaning requirements of the client.

If a prepreg without window is used, an ordinary prepreg such as an ordinary epoxy glass cloth sheet can be selected when stacking, which can greatly save costs, but when removing portions of the rigid sheet above the flexible regions, it may occur that portions of the rigid sheet corresponding to the rigid-flexible regions are removed somewhat along with the portions of the rigid sheet above the flexible regions, thereby resulting in delamination defect in the circuit board. If a prepreg with windows is used, when removing portions of the rigid sheets above the flexible regions, the portions of the rigid sheet corresponding to the rigid-flexible regions may not be removed jointly, which is caused by too much flow of the prepreg during laminating process; in order to avoid this situation, the prepreg with windows generally adopts a low flow prepreg or a no flow prepreg, which effectively avoid too much flow, but increase fabrication costs in comparison with the case where an ordinary prepreg is adopted.

In the above fabrication methods of a rigid-flexible PCB in these embodiments, through embedding the flexible board units in the rigid board, other than rigid-flexible regions and flexible regions in both of which flexible sheets are included, all other portions in the circuit board adopt rigid sheets, which greatly reduces utilization of flexible sheets and lowers fabrication costs; at the same time, processing flow of rigid regions can be performed exactly according to mature techniques of HDI and other rigid boards in the prior art, existing production devices of rigid boards can be directly used, which lowers procurement costs of production lines. Moreover, this method only involves embedding flexible boards in positions where flexible boards need to be provided in the rigid board, while the flexible boards have a smaller size than the rigid board in most cases, which greatly reduce the directly combined area of the flexible boards and the rigid board, especially, the flexible boards adopts small-size flexible boards with fabricated fine patterns (line widths/line spacings less than 75 μm/75 μm), which avoids difference in expansion and contraction variations between the rigid board and the flexible board, at the same time, drilling processes are mainly processed in the rigid regions, and thus the processing is easy to implement and the working accuracy of laminating, drilling or the like are improved greatly; furthermore, in the present invention, flexible board units are separately fabricated, the peelable protection films are adhered to both sides of the flexible sheets, such that the flexible regions can be effectively protected, and occurrence of poor connection of the entire PCB is avoided.

A fabrication method of a rigid-flexible PCB of the present invention and a fabrication method of a rigid-flexible PCB in the prior art are compared and analyzed, and see Table 1 for details:

TABLE 1

| | | fabrication method of a rigid-flexible | fabrication method of a rigid-flexible PCB with |
|---|---|---|---|
| | | PCB in the prior art | flexible boards partially embedded disclosed |
| | | | in the present invention |
| Structure | | [symbol] | [symbol] |
| Design | | Design of flexible board is restricted by rigid | Design of flexible board is not restricted by rigid |
| | | board, designed size of flexible board and rigid | board, it may be designed flexibly, especially a |
| | | board must be consistent with each other; | rigid-flexible board can be produced with |
| | | flexible board and rigid board with | small-size and low expansion and contraction |
| | | different materials and different sizes have | variations |
| | | different expansion and contraction variations, | |
| | | thus expansion and contraction ratios of flexible | |
| | | board should be reckoned in advance | |
| material | Flexible | An entire layer of a rigid-flexible board is a | Flexible boards are partially embedded in rigid-flexible |
| | boards | flexible board, increasing product costs; | board, overall size stability is the same as |
| | | flexible board has large expansion and | rigid board, rigid board regions can be designed |
| | | contraction variations, may easily deformed | completely according to design rules of rigid board; |
| | | and size stability thereof is not secured; | flexible board can be processed with small size, |
| | | large-size flexible board is difficult to process. | degree of difficulty of the processing is |
| | | | lowered and costs are saved |
| | Outer | Outer layer adjacent to flexible board need | Lamination may use ordinary prepreg, |
| | material | to adopt low flow prepreg to perform | no auxiliary material is required, costs |
| | | lamination, lamination need special | are saved |
| | | auxiliary material (cushion material), | |
| | | production costs are increased. | |
| Process | Laser | Three layers of materials: FR-4, PI and | Same as rigid board, only FR-4 material needs to be |
| techniques | drilling | adhesive need to be processed, processing | processed, existing processing parameters of |
| | | parameters need to be evaluated | rigid board can be used |
| | | Hole wall includes three kinds of materials: | Same as rigid board, side wall only has FR-4 material, |
| | | FR-4, PI and adhesive layer. PI is not resistant | and alkaline potassium permanganate can be |
| | | to strong alkali, adhesive layer is not | used for cleaning |
| | | resistant to strong acid or strong alkali, | |
| | | desmear process technique is thus limited, | |
| | | especially, desmear by using alkaline | |
| | | permanganate cleaning solution is limited. | |
| | | Although plasma desmear is equipments | |
| | | for such process are expensive and has | |
| | | limited working ability | |
| | Copper | As hole wall includes FR-4, PI and adhesive | Same as rigid board, side wall only has FR-4, and |
| | plating | layer, it is difficult to be plated, and | copper plating can be performed using rigid |
| | | undesirable phenomena such as thin coating | board method |
| | | layer or easily detachable coating layer | |
| | | are likely to occur | |

It can be seen from each item in the above table that beneficial effects of the present invention are as follows: by using the fabrication methods of a rigid-flexible PCB described in the present invention, fabrication costs and fabrication difficulties of rigid-flexible PCBs is significantly lowered, and production yield as well as product reliability is improved, especially to the connection reliability of products. Moreover, number of layers of a rigid-flexible board which can be fabricated is determined by the number of layers of rigid boards, it is especially suitable for fabricating high plus PCBs, and particularly for fabricating rigid-flexible PCBs with four or more than four layers.

It should be understood that the above implementations are only exemplary embodiments used to explain principals of the present invention. However, the present invention is not limited thereto. For the person skilled in the art, various modifications and improvements can be made without departing from the spirit and substance of the present invention, and these modifications and improvements are also deemed as the protection scope of the present invention.

1. A fabrication method of a rigid-flexible printed circuit board, comprising:
fabricating a rigid board including at least one flexible window region;
embedding at least one flexible board unit into the at least one flexible window region of the rigid board;
forming at least one build-up layer on one or both sides of the rigid board with the embedded flexible board unit; and
removing a portion covering a flexible region of the flexible board unit from the build-up layer, so as to form the rigid-flexible printed circuit board.

2. The fabrication method of claim 1, wherein the rigid board comprises a forming region, and the forming region comprises a rigid region and the at least one flexible window region;
the step of fabricating a rigid board including at least one flexible window region specifically includes:
performing pattern processing on the rigid region of a rigid sheet; and
performing window cutting on the rigid sheet, and a window position where the window cutting is performed forming the flexible window region of the rigid board.

3. The fabrication, method of claim 2, wherein, when performing the window cutting on the rigid sheet, the flexible window region has a same size as the flexible board unit which is embedded in a position corresponding to the flexible window region.

4. The fabrication method of claim 1, wherein,
the step of forming at least one build-up layer on one or both sides of the rigid board with the embedded flexible board unit comprises:
laminating a prepreg and a copper foil on one or both sides of the rigid board with the embedded flexible board unit, then performing drilling, plating and pattern transfer on the rigid board,
thus forming a first build-up layer on the rigid board with the embedded flexible board unit; or
continuously forming a second build-up layer according to the process sequence until multiple build-up layers are formed.

5. The fabrication method of claim 4, wherein the step of removing a portion covering a flexible region of the flexible board unit from the build-up layer comprises:
performing controlled-depth cutting on the build-up layer along a border of a region corresponding to the flexible region of the flexible board unit; and
removing the portion corresponding to the flexible region from the build-up layer.

6. The fabrication method of claim 4, wherein,
before laminating the prepreg, window cutting is performed on the prepreg, a window region cut in the prepreg corresponds to the flexible region of the flexible board unit, and a border of the window region corresponds to a common border of the flexible region and a rigid-flexible region of the flexible board unit; and
the prepreg is a low flow prepreg or a no flow prepreg.

7. The fabrication method of claim 6, wherein the window region of the prepreg has a same length as the rigid-flexible region, and has a width of 0-500 μm.

8. The fabrication method of claim 1, wherein, before embedding the at least one flexible board unit into the at least one flexible window region of the rigid board, the method further comprises fabricating the at least one flexible board unit, which comprises:
step S21: performing pattern processing on a flexible sheet;
step S23: bonding a peelable protection film onto the flexible sheet subjected to the pattern processing, bonded position of the peelable protection film corresponding to the flexible region of the flexible board unit.

9. The fabrication method of claim 10, wherein the step S23 further comprises:
performing window cutting on the peelable protection film, a window position of the peelable protection where the window cutting is performed corresponding to the rigid-flexible region of the flexible board unit;
bonding the peelable protection film subjected to the window cutting onto the cover film, the position in which the peelable protection film is bonded onto the cover film corresponding to the flexible region of the flexible board unit.

10. The fabrication method of claim 8, wherein between the step S21 and the step S23 further comprises step S22: covering the flexible sheet with a cover film; and in step S23, process of bonding the peelable protection film onto the flexible sheet subjected to the pattern processing specifically is: bonding the peelable protection film onto the flexible sheet subjected to the pattern processing by attaching the peelable protection film onto the cover film.

11. The fabrication method of claim 10, wherein,
in step S22, the cover film has a thickness ranging from 20 μm to 150 μm;
In step S23, the peelable protection film has a thickness ranging from 20 μm to 150 μm; and
wherein window cutting on the peelable protection film is performed by laser cutting, die cutting or mechanical milling.

12. A rigid-flexible printed circuit board, wherein the rigid-flexible PCB is fabricated by a fabrication method, and the fabrication method comprises:
fabricating a rigid board including at least one flexible window region;
embedding at least one flexible board unit into the at least one flexible window region of the rigid board;
forming at least one build-up layer on one or both sides of the rigid board with the embedded flexible board unit; and
removing a portion covering a flexible region of the flexible board unit from the build-up layer, so as to form the rigid-flexible printed circuit board.

13. The fabrication method of claim 4, wherein, before embedding the at least one flexible board unit into the at least one flexible window region of the rigid board, the method further comprises fabricating the at least one flexible board unit which comprises:
step S21: performing pattern processing on a flexible sheet;
step S23: bonding a peelable protection film onto the flexible sheet subjected to the pattern processing, bonded position of the peelable protection film corresponding to the flexible region of the flexible board unit.

14. The fabrication method of claim 6, wherein, before embedding the at least one flexible board unit into the at least one flexible window region of the rigid board, the method further comprises fabricating the at least one flexible board unit, which comprises:
step S21: performing pattern processing on a flexible sheet;
step S23: bonding a peelable protection film onto the flexible sheet subjected to the pattern processing, bonded position of the peelable protection film corresponding to the flexible region of the flexible board unit.

15. The fabrication method of claim 14, wherein between the step S21 and the step S23 further comprises step S22: covering the flexible sheet with a cover film; and in step S23, process of bonding the peelable protection film onto the flexible sheet subjected to the pattern processing specifically is: bonding the peelable protection film onto the flexible sheet subjected to the pattern processing by attaching the peelable protection film onto the cover film.

16. The fabrication method of claim 15, wherein the step S23 further comprises:
performing window cutting on the peelable protection film, a window position of the peelable protection where the window cutting is performed corresponding to the rigid-flexible region of the flexible board unit;
bonding the peelable protection film subjected to the window cutting onto the cover film, the position in which the peelable protection film is bonded onto the cover film corresponding to the flexible region of the flexible board unit.

17. The fabrication method of claim 15, wherein,
in step S22, the cover film has a thickness ranging from 20 μm to 150 μm;
In step S23, the peelable protection film has a thickness ranging from 20 μm to 150 μm; and
wherein window cutting on the peelable protection film is performed by laser cutting, die cutting or mechanical milling.

18. The rigid-flexible printed circuit board of claim 12, wherein the step of forming at least one build-up layer on one or both sides of the rigid board with the embedded flexible board unit comprises:
laminating a prepreg and a copper foil on one or both sides of the rigid board with the embedded flexible board unit, then performing drilling, plating and pattern transfer on the rigid board,
thus forming a first build-up layer on the rigid board with the embedded flexible board unit; or
continuously forming a second build-up layer according to the process sequence until multiple build-up layers are formed.

19. The rigid-flexible printed circuit board of claim 18, wherein before laminating the prepreg, window cutting is performed on the prepreg, a window region cut in the prepreg corresponds to the flexible region of the flexible board unit, and a border of the window region corresponds to a common border of the flexible region and a rigid-flexible region of the flexible board unit; and
the prepreg is a low flow prepreg or a no flow prepreg.

20. The rigid-flexible printed circuit board of claim 19, wherein the window region of the prepreg has a same length as the rigid-flexible region, and has a width of 0-500 μm.
